(19) United States
(12) Patent Application Publication
(10) Pub. No.: US 2026/0182216 A1
(43) Pub. Date: Jun. 25, 2026

(54) DISPLAY PANEL

(71) Applicants: Hefei Visionox Technology Co., Ltd., Hefei (CN); Visionox Technology Inc., Kunshan (CN)

(72) Inventors: Zhiwei ZHOU, Hefei (CN); Yingyu FENG, Kunshan (CN); Jinfang ZHANG, Hefei (CN); Run LI, Hefei (CN); Chunyang LIU, Kunshan (CN)

(73) Assignees: Hefei Visionox Technology Co., Ltd., Hefei (CN); Visionox Technology Inc., Kunshan (CN)

(21) Appl. No.: 19/403,202

(22) Filed: Nov. 27, 2025

(30) Foreign Application Priority Data
Dec. 23, 2024 (CN) 202411916403.0

(51) Int. Cl. H10K 59/80; H10K 59/122

(52) U.S. Cl. CPC H10K 59/873; H10K 59/122

(57) ABSTRACT

The present application provides a display panel. The display panel has an active area and a non-active area. The display panel includes: ; an isolation structure being provided with isolation openings in the active area; light-emitting devices, at least part of each of the light-emitting devices being located in the corresponding isolation opening; and at least one dam located on a side of the substrate, the at least one dam being located in the non-active area and at least partially surrounding the active area, where the at least one dam includes at least one first-type dam, the at least one first-type dam including a first blocking portion, the first blocking portion including one or more metal layers located on a side of the first electrode that is close to the substrate. According to the embodiments of the present application, the encapsulation reliability can be improved.

### CROSS REFERENCE TO RELATED APPLICATION

The present application claims priority to Chinese Patent Application No. 202411916403.0 filed on Dec. 23, 2024, which is incorporated herein by reference in its entirety.

### FIELD

The present application relates to the field of display technology, and in particular to a display panel and a preparation method therefor, and a display apparatus.

### BACKGROUND

With the development of display technology, organic light-emitting diodes (OLED) have been one of the commonly used display screens for mobile phones, tablet computers, smart televisions, smart wearable devices, and other electronic devices due to their advantages of low power consumption, high luminance, a wide angle of view, high contrast, etc. During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN 118251982 A, CN 116648095 A, CN 117062489 A, CN 118742138 A, CN 118678783 A, CN 118660598 A, CN 118675450 A, CN 118824188 A, and CN 118781966 A.

Light-emitting devices in OLEDs have poor stability and are highly sensitive to moisture and oxygen, making excellent encapsulation performance particularly crucial. However, existing display panels are subject to their structures and preparation processes, and thus need further improvement in their encapsulation reliability.

### SUMMARY

In order to solve the above problem, embodiments of the present application provide a display panel and a preparation method therefor, and a display apparatus.

One embodiment of the present application provides a display panel, which has an active area and a non-active area surrounding the active area. The display panel includes: a substrate; an isolation structure located on a side of the substrate, the isolation structure being provided with isolation openings in the active area; light-emitting devices, at least part of each of the light-emitting devices being located in the corresponding isolation opening, and the light-emitting device including a first electrode, a light-emitting functional unit, and a second electrode that are stacked in a direction away from the substrate; and one or more dams located on a side of the substrate, the one or more dams being located in the non-active area and at least partially surrounding the active area, where the one or more dams include at least one first-type dam, the first-type dam including a first blocking portion, the first blocking portion including one or more metal layers located on a side of the first electrode that is close to the substrate.

With reference to the embodiments, the first blocking portion further includes a first insulating layer, and the one or more metal layers are located on a side of the first insulating layer that is close to the substrate. In one embodiment, the first blocking portion further includes a second insulating layer located on a side of the first insulating layer that is close to the substrate, and the one or more metal layers include a first metal layer located between the first insulating layer and the second insulating layer. In one embodiment, the one or more metal layers further include a second metal layer located on a side of the second insulating layer that is close to the substrate. In one embodiment, an orthographic projection of the first insulating layer on the substrate covers an orthographic projection of the first metal layer on the substrate, and/or an orthographic projection of the second insulating layer on the substrate covers an orthographic projection of the second metal layer on the substrate. In one embodiment, a material of the first insulating layer includes an organic material, and/or a material of the second insulating layer includes an organic material. In one embodiment, the display panel further includes a first planarization layer, the first insulating layer being in the same layer as the first planarization layer; and/or the display panel further includes a second planarization layer, the second insulating layer being in the same layer as the second planarization layer. In one embodiment, the display panel further includes a third metal layer, the first metal layer being in the same layer as the third metal layer; and/or the display panel further includes a fourth metal layer, the second metal layer being in the same layer as the fourth metal layer.

With reference to the embodiments, the display panel further includes a gate drive circuit located in the non-active area, where an orthographic projection of the gate drive circuit on the substrate is on a side of orthographic projections of the one or more dams on the substrate that is close to the active area; and at least one metal layer extends, in a direction of the active area, to a side of the gate drive circuit that faces away from the substrate. In one embodiment, an orthographic projection of the at least one metal layer on the substrate covers the orthographic projection of the gate drive circuit on the substrate. In one embodiment, the at least one metal layer is configured to be connected to a constant potential. In one embodiment, the constant potential includes at least one of a positive supply voltage signal and a negative supply voltage signal. In one embodiment, the display panel further includes a third insulating layer located between the gate drive circuit and the at least one metal layer. In one embodiment, the display panel further includes a touch trace layer located on a side of the at least one metal layer that faces away from the substrate, where an orthographic projection of the touch trace layer on the substrate at least partially overlaps the orthographic projection of the gate drive circuit on the substrate.

With reference to the embodiments, at least one first-type dam further includes a second blocking portion located on a side of the first blocking portion that faces away from the substrate. In one embodiment, an orthographic projection of the second blocking portion on the substrate is within an orthographic projection of the first blocking portion on the substrate. In one embodiment, the second blocking portion includes a first sub-portion and a second sub-portion that are sequentially stacked in a direction away from the substrate, where an orthographic projection, on the substrate, of an edge of the second sub-portion on a side of the second sub-portion that is away from the active area is within an orthographic projection of the first sub-portion on the substrate. In one embodiment, the second blocking portion includes a first sub-portion and a second sub-portion that are sequentially stacked in a direction away from the substrate, where a surface of the second sub-portion on a side of the second sub-portion that is away from the active area is flush with a surface of the first sub-portion on a side of the first sub-portion that is away from the active area. In one embodiment, an orthographic projection, on the substrate, of an edge of the second sub-portion on a side of the second sub-portion that is close to the active area is on a side of an orthographic projection of a surface of the first sub-portion facing the second sub-portion on the substrate that is close to the active area. In one embodiment, the second blocking portion is provided in the same layer as the isolation structure. In one embodiment, the isolation structure includes a first portion and a second portion that are sequentially stacked in the direction away from the substrate, the first sub-portion being in the same layer as the first portion, and the second sub-portion being in the same layer as the second portion. In one embodiment, a material of the first sub-portion includes aluminum, and a material of the second sub-portion includes titanium. In one embodiment, the second blocking portion further includes a third sub-portion located on a side of the first sub-portion that is close to the substrate, and the isolation structure further includes a third portion located on a side of the first portion that is close to the substrate, the first sub-portion being in the same layer as the first portion. In one embodiment, a material of the third sub-portion includes molybdenum.

With reference to the embodiments, the one or more dams include a first dam and a second dam surrounding the first dam, where the first dam and the second dam are both the first-type dam, and the first dam includes a second blocking portion located on a side of the first blocking portion that faces away from the substrate, or the first dam and the second dam each include a second blocking portion located on a side of the first blocking portion that faces away from the substrate.

With reference to the embodiments, the one or more dams include second-type dams, the second-type dam including a third blocking portion, the third blocking portion including at least one insulating layer. In one embodiment, the one or more dams include a third dam and a fourth dam surrounding the third dam, where the third dam is the first-type dam and the fourth dam is the second-type dam, or the fourth dam is the first-type dam and the third dam is the second-type dam. In one embodiment, the third blocking portion includes a second insulating layer and a first insulating layer that are sequentially stacked in a direction away from the substrate. In one embodiment, at least one second-type dam includes a second blocking portion located on a side of the third blocking portion that faces away from the substrate, where an orthographic projection of the second blocking portion on the substrate is within an orthographic projection of the third blocking portion on the substrate.

With reference to the embodiments, the display panel further includes a pixel define layer partially located in the non-active area, where in the non-active area, an orthographic projection of the pixel define layer on the substrate covers an orthographic projection of the one or more dams on the substrate. In one embodiment, a material of the pixel define layer includes an inorganic material. In one embodiment, the pixel define layer has a thickness greater than or equal to 200 nm and less than or equal to 600 nm. In one embodiment, the pixel define layer is in contact with the first blocking portion. In one embodiment, the first-type dam further includes a second blocking portion, where an orthographic projection of the second blocking portion on the substrate is within an orthographic projection of the first blocking portion on the substrate, and the second blocking portion is located on a side of the pixel define layer that faces away from the substrate. In one embodiment, the pixel define layer is provided with pixel openings in the active area, where an orthographic projection of the isolation opening on the substrate covers an orthographic projection of the corresponding pixel opening on the substrate. In one embodiment, the display panel further includes a first encapsulation layer located on a side of the light-emitting devices that faces away from the substrate, the first encapsulation layer including encapsulation units which are spaced apart from each other and correspond to the light-emitting devices, where an orthographic projection of the encapsulation unit on the substrate covers at least part of an orthographic projection of the light-emitting device on the substrate. In one embodiment, the display panel further includes a second encapsulation layer located on a side of the first encapsulation layer that is away from the substrate, the second encapsulation layer extending from the active area to the non-active area and terminating on a side of the one or more dams that is close to the active area. In one embodiment, the display panel further includes a third encapsulation layer located on a side of the second encapsulation layer that faces away from the substrate, where the third encapsulation layer extends from the active area to the non-active area, and in the non-active area, the third encapsulation layer is at least partially in contact with the pixel define layer. In one embodiment, materials of the first encapsulation layer and the third encapsulation layer include inorganic materials, and a material of the second encapsulation layer includes an organic material.

In a second aspect, an embodiment of the present application further provides a display panel, which has an active area and a non-active area surrounding the active area. The display panel includes: a substrate; and one or more dams located on a side of the substrate, the one or more dams being located in the non-active area and at least partially surrounding the active area, where the one or more dams include at least one first-type dam, the first-type dam including a second blocking portion, the second blocking portion including a first sub-portion and a second sub-portion that are sequentially stacked in a direction away from the substrate, where an orthographic projection, on the substrate, of an edge of the second sub-portion on a side of the second sub-portion that is away from the active area is within an orthographic projection of the first sub-portion on the substrate.

With reference to the second aspect, the first-type dam further includes a first blocking portion located on a side of the second blocking portion that is close to the substrate, where an orthographic projection of the second blocking portion on the substrate is within an orthographic projection of the first blocking portion on the substrate, and the first blocking portion includes one or more metal layers. In one embodiment, a surface of the second sub-portion on a side of the second sub-portion that is away from the active area is flush with a surface of the first sub-portion on a side of the first sub-portion that is away from the active area. In one embodiment, an orthographic projection, on the substrate, of an edge of the second sub-portion on a side of the second sub-portion that is close to the active area is on a side of an orthographic projection of a surface of the first sub-portion facing the second sub-portion on the substrate that is close to the active area. In one embodiment, the display panel further includes an isolation structure located in the active area and located on a side of the substrate, the second blocking portion being provided in the same layer as the isolation structure. In one embodiment, the isolation structure includes a first portion and a second portion that are sequentially stacked in the direction away from the substrate, the first sub-portion being in the same layer as the first portion, and the second sub-portion being in the same layer as the second portion. In one embodiment, a material of the first sub-portion includes aluminum, and a material of the second sub-portion includes titanium. In one embodiment, the second blocking portion further includes a third sub-portion located on a side of the first sub-portion that is close to the substrate, and the isolation structure further includes a third portion located on a side of the first portion that is close to the substrate, the first sub-portion being in the same layer as the first portion. In one embodiment, a material of the third sub-portion includes molybdenum.

With reference to the second aspect, the one or more dams further include at least one second-type dam, the second-type dam including a third blocking portion, the third blocking portion including at least one insulating layer. In one embodiment, the third blocking portion includes a second insulating layer and a first insulating layer that are sequentially stacked in a direction away from the substrate. In one embodiment, at least one second-type dam includes a second blocking portion located on a side of the third blocking portion that faces away from the substrate, where an orthographic projection of the second blocking portion on the substrate is within an orthographic projection of the third blocking portion on the substrate.

In a third aspect, an embodiment of the present application further provides a display panel, which has an active area and a non-active area surrounding the active area. The display panel includes: a substrate; and one or more dams located on a side of the substrate, the one or more dams being located in the non-active area and at least partially surrounding the active area, where the one or more dams include at least one second-type dam, the second-type dam including a third blocking portion and a second blocking portion that are sequentially stacked in a direction away from the substrate, where an orthographic projection of the second blocking portion on the substrate is within an orthographic projection of the third blocking portion on the substrate, and the third blocking portion includes at least one insulating layer.

With reference to the third aspect, the third blocking portion includes a second insulating layer and a first insulating layer that are sequentially stacked in a direction away from the substrate. In one embodiment, the second blocking portion includes a first sub-portion and a second sub-portion that are sequentially stacked in a direction away from the substrate, where an orthographic projection, on the substrate, of an edge of the second sub-portion on a side of the second sub-portion that is away from the active area is within an orthographic projection of the first sub-portion on the substrate. In one embodiment, a surface of the sub-portion on a side of the second blocking portion that is away from the active area is flush with a surface of the first sub-portion on a side of the first sub-portion that is away from the active area. In one embodiment, an orthographic projection, on the substrate, of an edge of the second sub-portion on a side of the second sub-portion that is close to the active area is on a side of an orthographic projection of a surface of the first sub-portion facing the second sub-portion on the substrate that is close to the active area. In one embodiment, the display panel further includes an isolation structure located in the active area and located on a side of the substrate, the isolation structure including a first portion and a second portion that are sequentially stacked in the direction away from the substrate, the first sub-portion being in the same layer as the first portion, and the second sub-portion being in the same layer as the second portion. In one embodiment, a material of the first sub-portion includes aluminum, and a material of the second sub-portion includes titanium. In one embodiment, the second blocking portion further includes a third sub-portion located on a side of the first sub-portion that is close to the substrate, and the isolation structure further includes a third portion located on a side of the first portion that is close to the substrate, the first sub-portion being in the same layer as the first portion. In one embodiment, a material of the third sub-portion includes molybdenum.

With reference to the third aspect, the one or more dams further include at least one first-type dam, the first-type dam including a first blocking portion, the first blocking portion including one or more metal layers. In one embodiment, the first-type dam further includes a second blocking portion located on a side of the first blocking portion that faces away from the substrate, where an orthographic projection of the second blocking portion on the substrate is within an orthographic projection of the first blocking portion on the substrate.

In a fourth aspect, an embodiment of the present application further provides a preparation method for a display panel, where the display panel includes an active area and a non-active area surrounding the active area. The method includes: preparing one or more dams on a side of a substrate, the dams being located in the non-active area and at least partially surrounding the active area, where the one or more dams include at least one first-type dam, the first-type dam including a first blocking portion, the first blocking portion including one or more metal layers.

With reference to the fourth aspect, the preparing one or more dams on a side of a substrate includes: preparing a second insulating material layer on a side of the substrate, and patterning the second insulating material layer to obtain a second planarization layer and a second insulating layer; preparing a first metal material layer on a side of the second insulating layer that faces away from the substrate, and patterning the first metal material layer to obtain a third metal layer and a first metal layer; and preparing a first insulating material layer on a side of the first metal layer that faces away from the substrate, and patterning the first insulating material layer to obtain a first planarization layer and a first insulating layer, where the second insulating layer, the first metal layer, and the first insulating layer constitute the first blocking portion. In one embodiment, before the preparing a second insulating material layer on a side of the substrate, the method further includes: preparing a second metal material layer on a side of the substrate, and patterning the second metal material layer to obtain a fourth metal layer and a second metal layer, where the second metal layer, the second insulating layer, the first metal layer, and the first insulating layer constitute the first blocking portion. In one embodiment, before the preparing one or more dams on a side of a substrate, the method further includes: preparing a gate drive circuit on a side of the substrate, where the gate drive circuit is located in the non-active area, and an orthographic projection of the gate drive circuit on the substrate is on a side of an orthographic projection of the one or more dams on the substrate that is close to the active area. In one embodiment, the patterning the first metal material layer includes: patterning the first metal material layer, and the first metal layer covers the gate drive circuit; and/or the patterning the second metal material layer includes: patterning the second metal material layer, and the second metal layer covers the gate drive circuit. In one embodiment, after the preparing a gate drive circuit on a side of the substrate, the method further includes: preparing a third insulating layer on a side of the gate drive circuit that faces away from the substrate.

With reference to the fourth aspect, the one or more dams further include at least one second-type dam, the second-type dam including a third blocking portion, the third blocking portion including at least one insulating layer. The preparing one or more dams on a side of a substrate includes: preparing a second insulating material layer on a side of the substrate, and patterning the second insulating material layer to obtain a second planarization layer and a second insulating layer; preparing a first insulating material layer on a side of the second insulating layer that faces away from the substrate, and patterning the first insulating material layer to obtain a first planarization layer and a first insulating layer, where the first insulating layer and the second insulating layer constitute the third blocking portion.

With reference to the fourth aspect, after the preparation of the first planarization layer and the first insulating layer, the method further includes: sequentially preparing a first conductive material layer and a second conductive material layer on a side of the first insulating layer that faces away from the substrate; performing a first patterning process on the first conductive material layer and the second conductive material layer to obtain an intermediate structure, the intermediate structure including a first intermediate sub-structure located in the active area and a second intermediate sub-structure located in the non-active area; coating a photoresist on at least part of a surface of the second intermediate sub-structure that faces away from the substrate; and performing a second patterning process on the first intermediate sub-structure and/or the second intermediate sub-structure, and removing the photoresist to obtain an isolation structure located in the active area and a second blocking portion located in the non-active area, the second blocking portion being located on a side of the first blocking portion and/or the third blocking portion that faces away from the substrate. In one embodiment, the first patterning process includes dry etching, and the second patterning process includes wet etching. In one embodiment, before the sequentially preparing a first conductive material layer and a second conductive material layer on a side of the first insulating layer that faces away from the substrate, the method further includes: preparing a third conductive material layer on a side of the first insulating layer that faces away from the substrate; and after the sequentially preparing a first conductive material layer and a second conductive material layer on a side of the first insulating layer that faces away from the substrate, the method further includes: performing a first patterning process on the first conductive material layer, the second conductive material layer, and the third conductive material layer to obtain an intermediate structure.

With reference to the fourth aspect, after the preparation of the first planarization layer and the first insulating layer, the method further includes: preparing a pixel define layer on a side of the first insulating layer that faces away from the substrate, where the pixel define layer extends from the active area to the non-active area, the pixel define layer is in contact with the first blocking portion and/or the third blocking portion, and the pixel define layer is provided with pixel openings in the active area. In one embodiment, before the preparing a pixel define layer on a side of the first insulating layer that faces away from the substrate, the method further includes: preparing first electrodes on the side of the first insulating layer that faces away from the substrate, where the first electrode is partially exposed out of the pixel opening; and after the preparing a pixel define layer on a side of the first insulating layer that faces away from the substrate, the method further includes: sequentially preparing light-emitting functional units and second electrodes on a side of the pixel define layer that faces away from the substrate, where the first electrode, the light-emitting functional unit, and the second electrode constitute a light-emitting device, the light-emitting device being at least partially located within the pixel opening. In one embodiment, after the preparation of the second electrodes, the method further includes: preparing a first encapsulation layer on a side of the second electrodes that faces away from the substrate, the first encapsulation layer including encapsulation units which are spaced apart from each other and correspond to the light-emitting devices, where an orthographic projection of the encapsulation unit on the substrate covers at least part of an orthographic projection of the light-emitting device on the substrate. In one embodiment, after the preparing a first encapsulation layer on a side of the second electrodes that faces away from the substrate, the method further includes: sequentially preparing a second encapsulation layer and a third encapsulation layer on a side of the first encapsulation layer that faces away from the substrate, the second encapsulation layer extending from the active area to the non-active area and terminating on a side of the one or more dams that is close to the active area, where the third encapsulation layer extends from the active area to the non-active area, and in the non-active area, the third encapsulation layer is at least partially in contact with the pixel define layer. In one embodiment, after the preparation of the third encapsulation layer, the method further includes: preparing a touch trace layer on a side of the third encapsulation layer that faces away from the substrate.

In a fifth aspect, an embodiment of the present application further provides a display apparatus including the display panel as described above, or including a display panel prepared by the above-described preparation method for a display panel.

With the above embodiment, the use of the metal layers to raise the height of the one or more dams can prevent overflow during subsequent preparation of the organic encapsulation layers, thereby improving the encapsulation reliability of the display panel.

### BRIEF DESCRIPTION OF THE DRAWINGS

FIG. 1 is a structural schematic top view of a display panel according to an embodiment of the present application.

FIG. 2 is a structural schematic cross-sectional view of a display panel according to an embodiment of the present application.

FIG. 3 is a structural schematic cross-sectional view of a display panel according to another embodiment of the present application.

FIG. 4 is a structural schematic cross-sectional view of a display panel according to another embodiment of the present application.

FIG. 5 is a structural schematic cross-sectional view of a display panel according to another embodiment of the present application.

FIG. 6 is a structural schematic cross-sectional view of a display panel according to another embodiment of the present application.

FIG. 7 is a structural schematic cross-sectional view of a display panel according to another embodiment of the present application.

FIG. 8 is a structural schematic cross-sectional view of a display panel according to another embodiment of the present application.

FIG. 9 is a structural schematic cross-sectional view of a display panel according to another embodiment of the present application.

FIG. 10 is a structural schematic cross-sectional view of a display panel according to another embodiment of the present application.

FIG. 11 is a schematic flowchart of a preparation method for a display panel according to an embodiment of the present application.

FIG. 12 is a schematic structural diagram of a display apparatus according to an embodiment of the present application.

### DETAILED DESCRIPTION OF THE EMBODIMENTS

The embodiments of the present application will be clearly and completely described below with reference to the drawings in the embodiments of the present application. The embodiments described are merely some rather than all of the embodiments of the present application.

In the preparation of a display panel, a functional film layer in a light-emitting unit needs to be formed by means of evaporation, and instances of alignment are required during evaporation of the functional film layer via a fine metal mask (FMM). In order to solve the problem of position offset caused by an alignment error, enough space needs to be reserved between different light-emitting units, which results in a reduced opening rate of the light-emitting units, making it difficult to improve the pixel density of the display panel.

In the present application, instead of using a mask, a full-surface evaporation process is used to individually evaporate and encapsulate light-emitting units of different colors (also referred to as different sub-pixels) without consideration of the alignment accuracy during evaporation. Therefore, the gap between the light-emitting units can be designed to be smaller, thereby improving the pixel density. However, in this case, the display panel has a relatively low dam height in a bezel area, and is prone to overflow during preparation of organic encapsulation layers, affecting the encapsulation reliability of products.

In view of the above problems, an embodiment of the present application provides a display panel, which has an active area and a non-active area surrounding the active area. The display panel includes: a substrate; an isolation structure located on a side of the substrate, the isolation structure being provided with isolation openings in the active area; light-emitting devices, at least part of each of the light-emitting devices being located in the corresponding isolation opening, and the light-emitting device including a first electrode, a light-emitting functional unit, and a second electrode that are stacked in a direction away from the substrate; and one or more dams located on a side of the substrate, the dams being located in the non-active area and at least partially surrounding the active area, where the one or more dams include at least one first-type dam, the first-type dam including a first blocking portion, the first blocking portion including one or more metal layers located on a side of the first electrode that is close to the substrate. In this embodiment of the present application, the use of the metal layers to raise the height of the dams can prevent overflow during subsequent preparation of the organic encapsulation layers, thereby improving the encapsulation reliability of the display panel.

The embodiments of the present application are illustrated below through embodiments. It should be understood that the following embodiments are for illustrative purposes only and are not intended to limit the scope of protection of the present application.

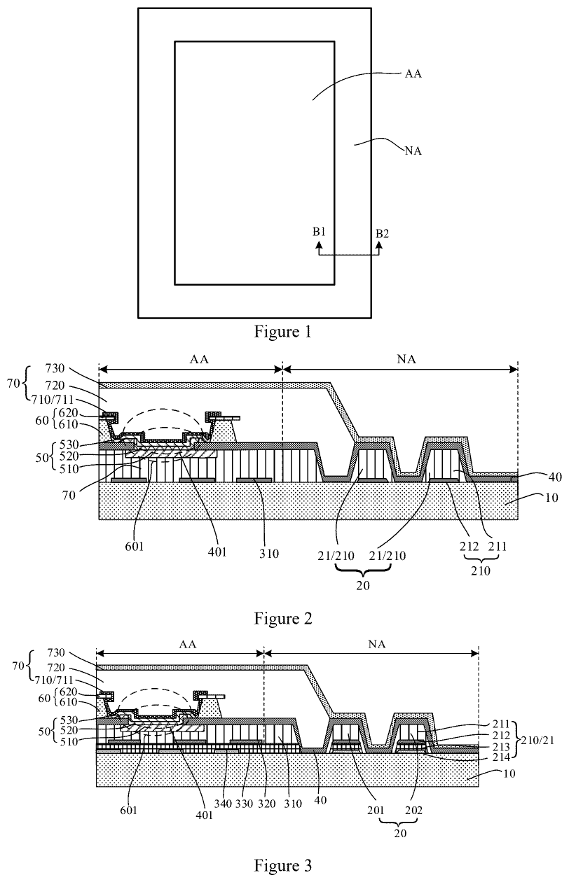

FIG. 1 is a structural schematic top view of a display panel according to an embodiment of the present application. FIG. 2 is a structural schematic cross-sectional view of a display panel according to an embodiment of the present application. In one embodiment, FIG. 2 is a structural schematic cross-sectional view of the display panel in FIG. 1 along line B1B2.

As shown in FIGS. 1 and 2, the display panel has an active area AA and a non-active area NA surrounding the active area AA. The display panel includes a substrate 10 and one or more dams 20. The dams 20 are located on a side of the substrate 10, and the dams 20 are located in the non-active area NA and at least partially surround the active area AA. In this embodiment of the present application, the one or more dams 20 include at least one first-type dam 21. The first-type dam 21 includes a first blocking portion 210, the first blocking portion 210 including one or more metal layers, for example, a first metal layer 212. In this way, the use of the metal layer to raise the height of the dams can prevent overflow during subsequent preparation of organic encapsulation layers, thereby improving the encapsulation reliability of the display panel.

In this embodiment of the present application, In one embodiment, the metal layer is located inside the first blocking portion 210. In one embodiment, as shown in FIG. 2, the first blocking portion 210 further includes a first insulating layer 211, and the one or more metal layers are located on a side of the first insulating layer 211 that is close to the substrate 10. For example, the one or more metal layers include the first metal layer 212, and the first metal layer 212 is located on the side of the first insulating layer 211 that is close to the substrate 10. An orthographic projection of the first insulating layer 211 on the substrate 10 covers an orthographic projection of the first metal layer 212 on the substrate 10.

In this embodiment of the present application, the first insulating layer 211 and the first metal layer 212 may be prepared in the same layer as other film layers of the display panel. For example, the display panel includes a first planarization layer 310 and a third metal layer 320. The first planarization layer 310 is in the same layer as the first insulating layer 211, and the third metal layer 320 is in the same layer as the first metal layer 212. In this way, the preparation process can be simplified, and the preparation efficiency can be improved.

FIG. 3 is a structural schematic cross-sectional view of a display panel according to another embodiment of the present application. The display panel shown in FIG. 3 differs from the display panel shown in FIG. 2 in that the first blocking portion 210 further includes a second insulating layer 213 and a second metal layer 214. The second insulating layer 213 is located on a side of the first metal layer 212 that is close to the substrate 10. The second metal layer 214 is located on a side of the second insulating layer 213 that is close to the substrate 10. An orthographic projection of the second insulating layer 213 on the substrate 10 covers an orthographic projection of the second metal layer 214 on the substrate 10. In this embodiment of the present application, the use of the first metal layer 212 and the second metal layer 214 to increase the height of the first blocking portion 210 (or of the first-type dam 21) can prevent overflow during subsequent preparation of organic encapsulation layers, thereby improving the encapsulation reliability of the display panel. It should be understood that two metal layers are used here as an example for illustration. In other embodiments, other numbers of metal layers may also be used, such as one metal layer (as shown in FIG. 2) and three metal layers. This is not limited in the present application.

In this embodiment of the present application, a material of the first insulating layer 211 includes an organic material, and/or a material of the second insulating layer 213 includes an organic material. In this embodiment of the present application, the first insulating layer 211, the first metal layer 212, the second insulating layer 213, and the second metal layer 214 may be prepared in the same layer as some of film layers of the display panel.

With continued reference to FIG. 3, the display panel further includes a first planarization layer 310, a third metal layer 320, a second planarization layer 330, and a fourth metal layer 340. In this embodiment of the present application, the first insulating layer 211 is in the same layer as the first planarization layer 310, and/or the second insulating layer 213 is in the same layer as the second planarization layer 330. The first metal layer 212 is in the same layer as the third metal layer 320, and/or the second metal layer 214 is in the same layer as the fourth metal layer 340. For example, the third metal layer 320 is an M4 metal layer, and the fourth metal layer 340 is an M3 metal layer. In this way, the preparation process can be simplified, and the preparation efficiency can be improved.

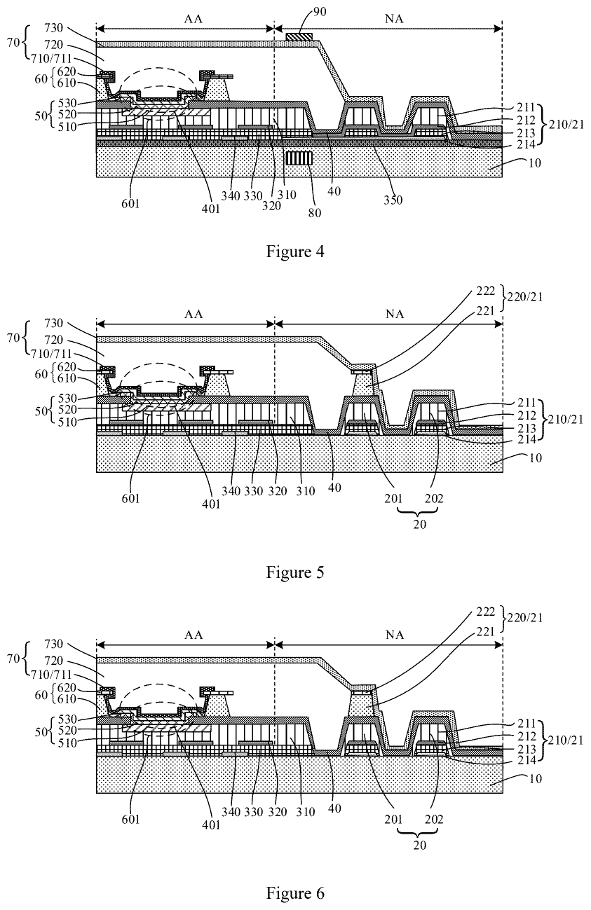

FIG. 4 is a structural schematic cross-sectional view of a display panel according to another embodiment of the present application. The display panel shown in FIG. 4 differs from the display panel shown in FIG. 3 in that the former further includes a gate drive circuit 80. The gate drive circuit 80 is located in the non-active area NA, and an orthographic projection of the gate drive circuit 80 on the substrate 10 is located on a side of an orthographic projection of the dams 20 on the substrate 10 that is close to the active area AA. At least one metal layer (e.g., the first metal layer 212, the second metal layer 214) extends, in a direction of the active area AA, to a side of the gate drive circuit 80 that faces away from the substrate 10. An orthographic projection of the at least one metal layer on the substrate 10 covers the orthographic projection of the gate drive circuit 80 on the substrate 10. In this embodiment of the present application, the at least one metal layer is configured to be connected to a constant potential. Here, the constant potential includes at least one of a positive supply voltage signal and a negative supply voltage signal. It should be noted that in this embodiment of the present application, only one metal layer may extend to the side of the gate drive circuit 80 that faces away from the substrate 10, or metal layers may extend to the side of the gate drive circuit 80 that faces facing away from the substrate 10. In the case that metal layers extend to the side of the gate drive circuit 80 that faces away from the substrate 10, the metal layers are configured to be connected to the same constant potential. For example, the first metal layer 212 extends, in the direction of the active area AA, to the side of the gate drive circuit 80 that faces away from the substrate 10; or the second metal layer 214 extends, in the direction of the active area AA, to the side of the gate drive circuit 80 that faces away from the substrate 10; or both the first metal layer 212 and the second metal layer 214 extend, in the direction of the active area AA, to the side of the gate drive circuit 80 that faces away from the substrate 10, in which case the first metal layer 212 and the second metal layer 214 need to be connected to the same constant potential.

In this embodiment of the present application, the display panel further includes a third insulating layer 350. The third insulating layer 350 is located between the gate drive circuit 80 and the at least one metal layer. For example, the third insulating layer 350 is located between the second metal layer 214 and the gate drive circuit 80. In one embodiment, the third insulating layer 350 includes an inorganic material, which can prevent electrical conduction between the second metal layer 214 and the gate drive circuit 80.

With continued reference to FIG. 4, the display panel further includes a touch trace layer 90. The touch trace layer 90 is located on a side of the at least one metal layer that faces away from the substrate 10. In one embodiment, the touch trace layer 90 is located on a side of an encapsulation layer 70 that faces away from the substrate. Here, an orthographic projection of the touch trace layer 90 on the substrate 10 at least partially overlaps the orthographic projection of the gate drive circuit 80 on the substrate 10. In this embodiment of the present application, at least one metal layer is provided between the touch trace layer 90 and the gate drive circuit 80, which can shield signal interference between the touch trace layer 90 and the gate drive circuit 80, thereby enhancing the touch sensitivity and the touch accuracy.

With continued reference to FIG. 3, the one or more dams 20 include a first dam 201 and a second dam 202. The second dam 202 surrounds the first dam 201, and the first dam 201 and the second dam 202 are both the first-type dam. That is, in this embodiment of the present application, the two dams 20 may each be provided with a metal layer, which can better prevent overflow, thereby improving the encapsulation effect.

In this embodiment of the present application, in order to better prevent overflow, at least one first-type dam further includes a second blocking portion 220. The second blocking portion 220 is located on a side of the first blocking portion 210 that faces away from the substrate 10. This is specifically as shown in FIGS. 5 to 7.

FIG. 5 is a structural schematic cross-sectional view of a display panel according to another embodiment of the present application. The display panel shown in FIG. 5 differs from the display panel shown in FIG. 3 in that the first dam 201 and the second dam 202 are both the first-type dam 21, and the first dam 201 includes the second blocking portion 220, where the second blocking portion 220 is located on the side of the first blocking portion 210 that faces away from the substrate 10, and an orthographic projection of the second blocking portion 220 on the substrate 10 is within an orthographic projection of the first blocking portion 210 on the substrate 10; and the second dam 202 does not include the second blocking portion 220. In one embodiment, the second blocking portion 220 includes a first sub-portion 221 and a second sub-portion 222 that are sequentially stacked in a direction away from the substrate 10. An orthographic projection, on the substrate 10, of an edge of the second sub-portion 222 on a side of the second sub-portion that is away from the active area AA is within an orthographic projection of the first sub-portion 221 on the substrate 10. In one embodiment, a surface of the second sub-portion 222 on a side of the second sub-portion that is away from the active area AA is flush with a surface of the first sub-portion 221 on a side of the first sub-portion that is away from the active area AA. In one embodiment, an orthographic projection, on the substrate 10, of an edge of the second sub-portion 222 on a side of the second sub-portion that is close to the active area AA is on a side of an orthographic projection of a surface of the first sub-portion 221 facing the second sub-portion 222 on the substrate 10 that is close to the active area AA. That is, on the side close to the active area AA, the first sub-portion 221 is laterally etched; and on the side away from the active area AA, the first sub-portion 221 is not laterally etched. In this way, a sidewall in contact with a second encapsulation layer 730 does not have a laterally etched structure, which will not affect the deposition thickness of the second encapsulation layer 730, thereby improving the encapsulation reliability.

In this embodiment of the present application, the display panel further includes an isolation structure 60. The isolation structure 60 is located in the active area AA. In one embodiment, the second blocking portion 220 is provided in the same layer as the isolation structure 60. The isolation structure 60 includes a first portion 610 and a second portion 620 that are sequentially stacked in a direction away from the substrate 10. An orthographic projection of the first portion 610 on the substrate 10 is within an orthographic projection of the second portion 620 on the substrate 10. In one embodiment, the first sub-portion 221 is in the same layer as the first portion 610, and the second sub-portion 222 is in the same layer as the second portion 620. That is, the second blocking portion 220 may be prepared at the same time as the isolation structure 60, which can simplify the preparation process and improve the preparation efficiency.

In one embodiment, the second blocking portion 220 further includes a third sub-portion 223. The third sub-portion 223 is located on a side of the first sub-portion 221 that is close to the substrate 10. The isolation structure 60 further includes a third portion 630. The third portion 630 is located on a side of the first portion 610 that is close to the substrate 10. The first sub-portion 221 is in the same layer as the third portion 630.

FIG. 6 is a structural schematic cross-sectional view of a display panel according to another embodiment of the present application. The display panel shown in FIG. 6 differs from the display panel shown in FIG. 5 in that an orthographic projection, on the substrate 10, of an edge of the second sub-portion 222 on a side of the second sub-portion that is close to the active area AA is within an orthographic projection of the first sub-portion 221 on the substrate 10. That is, in this embodiment of the present application, the first sub-portion 221 is not laterally etched on the side close to the active area AA or on the side away from the active area AA. In this case, the encapsulation reliability can also be improved.

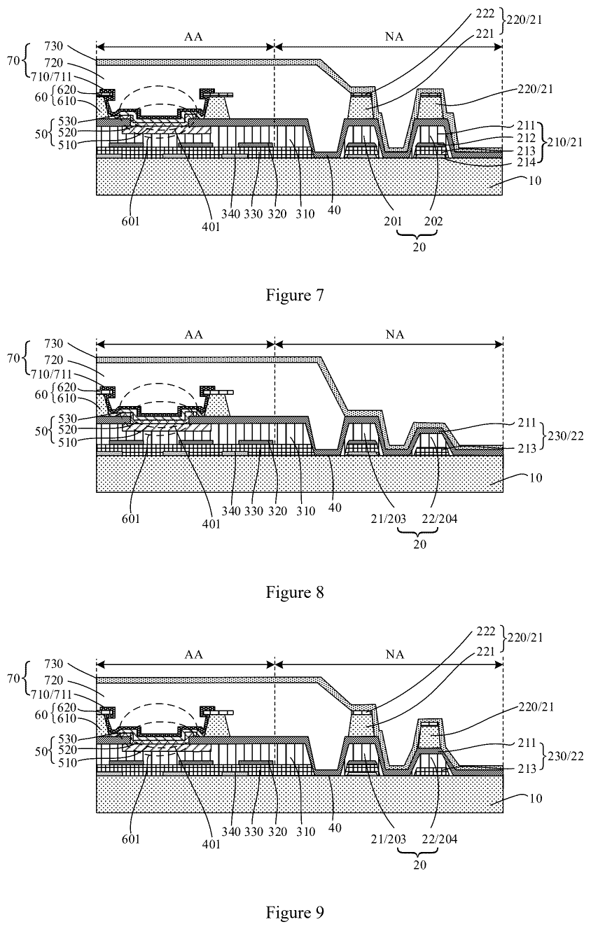

FIG. 7 is a structural schematic cross-sectional view of a display panel according to another embodiment of the present application. The display panel shown in FIG. 7 differs from the display panel shown in FIG. 6 in that the first dam 201 and the second dam 202 each include the second blocking portion 220. The second blocking portion 220 is located on the side of the first blocking portion 210 that faces away from the substrate 10. Since a sidewall of the second blocking portion 220 of the second dam 202 needs to be in contact with the second encapsulation layer 730, the first sub-portion 221 of the second blocking portion 220 of the second dam 202 should not be laterally etched, to avoid affecting the encapsulation reliability. In this embodiment of the present application, neither of the first sub-portions 221 of the second blocking portions 220 of the first dam 201 and the second dam 202 are laterally etched. By providing two second blocking portions 220, the encapsulation reliability can be further improved.

In some embodiments, the one or more dams further include at least one second-type dam, the second-type dam including a third blocking portion. The third blocking portion includes at least one insulating layer. The one or more dams include a third dam and a fourth dam surrounding the third dam, where the third dam is the first-type dam and the fourth dam is the second-type dam, or the fourth dam is the first-type dam and the third dam is the second-type dam. That is, it is possible to effectively prevent overflow by adding a metal layer only on top of one dam.

For example, FIG. 8 is a structural schematic cross-sectional view of a display panel according to another embodiment of the present application. As shown in FIG. 8, the one or more dams include a third dam 203 and a fourth dam 204, the fourth dam 204 surrounding the third dam 203. The third dam 203 is the first-type dam 21, and the fourth dam 204 is the second-type dam 22. The first-type dam 21 (or the third dam 203) includes the first blocking portion 210. The first blocking portion 210 includes the second metal layer 214, the second insulating layer 213, the first metal layer 212, and the first insulating layer 211 that are sequentially stacked in the direction away from the substrate 10. The second-type dam 22 (or the fourth dam 204) includes a third blocking portion 230. The third blocking portion 230 includes the second insulating layer 213 and the first insulating layer 211 that are sequentially stacked in the direction away from the substrate 10. In this embodiment of the present application, it is possible to achieve the effect of preventing overflow by adding a metal layer only on top of the third dam 203. It should be understood that it is also possible to achieve the effect of preventing overflow by adding a metal layer only on top of the fourth dam 204. This is not limited in the embodiments of the present application.

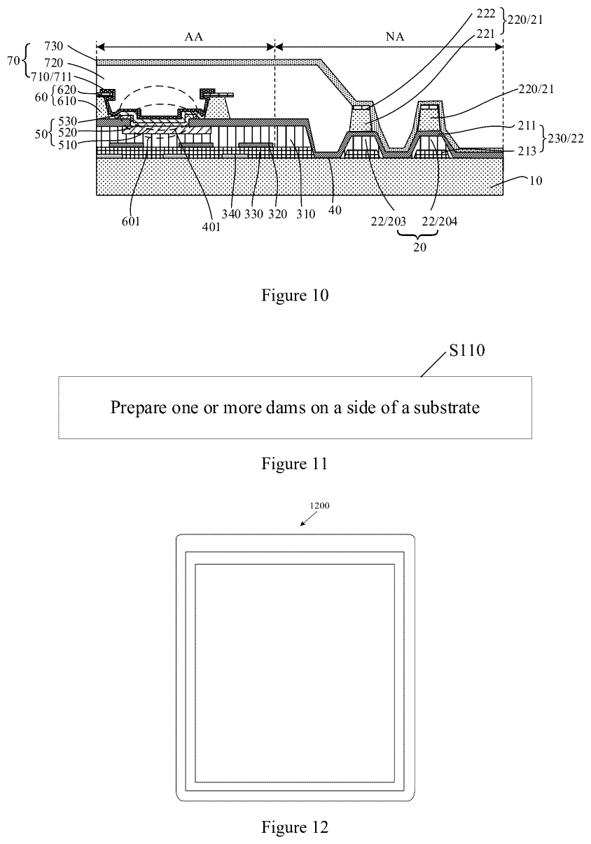

In some embodiments, to better increase the height of the dams 20, the second blocking portion 220 may be provided on a side of the first blocking portion 210 and/or the third blocking portion 230 that faces away from the substrate 10. This is specifically as shown in FIGS. 9 and 10.

FIG. 9 is a structural schematic cross-sectional view of a display panel according to another embodiment of the present application. The display panel shown in FIG. 9 differs from the display panel shown in FIG. 8 in that the first-type dam 21 (or the third dam 203) further includes the second blocking portion 220, the second blocking portion 220 being located on the side of the first blocking portion 210 that faces away from the substrate 10, where the orthographic projection of the second blocking portion 220 on the substrate 10 is within the orthographic projection of the first blocking portion 210 on the substrate 10; and the second-type dam 22 (or the fourth dam 204) further includes the second blocking portion 220, the second blocking portion 220 being located on the side of the third blocking portion 230 that faces away from the substrate 10, where the orthographic projection of the second blocking portion 220 on the substrate 10 is within an orthographic projection of the third blocking portion 230 on the substrate 10. In this embodiment of the present application, neither of the first sub-portions 221 of the second blocking portions 220 of the third dam 203 and the fourth dam 204 are laterally etched. In other embodiments, the side of the first sub-portion 221 of the second blocking portion 220 of the third dam 203 that is close to the active area may be laterally etched, in which case the encapsulation reliability is not affected. In other embodiments, the second blocking portion 220 may be provided only on a side of the first blocking portion 221 that faces away from the substrate 10, or the second blocking portion 220 may be provided only on the side of the third blocking portion 230 that faces away from the substrate 10, both of which can prevent overflow. This is not limited in the embodiments of the present application.

FIG. 10 is a structural schematic cross-sectional view of a display panel according to another embodiment of the present application. The display panel shown in FIG. 10 differs from the display panel shown in FIG. 9 in that the third dam 203 and the fourth dam 204 are both the second-type dams 22. That is, the third dam 203 and the fourth dam 204 each include a third blocking portion 230 and a second blocking portion 220, where the second blocking portion 220 is located on the side of the third blocking portion 230 that faces away from the substrate 10, and the orthographic projection of the second blocking portion 220 on the substrate 10 is within the orthographic projection of the third blocking portion 230 on the substrate 10. In this embodiment of the present application, providing the second blocking portion 220 on the third blocking portion 230 can prevent overflow, thereby improving the encapsulation reliability.

With continued reference to FIGS. 2 to 10, the display panel further includes a pixel define layer 40. The pixel define layer 40 is partially located in the non-active area NA. In the non-active area NA, an orthographic projection of the pixel define layer 40 on the substrate 10 covers the orthographic projection of the dams 20 on the substrate 10. In one embodiment, the pixel define layer 40 is in contact with the first blocking portion 210 and/or the third blocking portion 230. The pixel define layer 40 is located between the first blocking portion 210 and the second blocking portion 220, and/or the pixel define layer is located between the third blocking portion 230 and the second blocking portion 220. In this embodiment of the present application, a material of the pixel define layer 40 includes an inorganic material. In one embodiment, the pixel define layer 40 has a thickness greater than or equal to 200 nm and less than or equal to 600 nm. For example, the pixel define layer 40 has a thickness of 200 nm, 300 nm, 400 nm, 500 nm, or 600 nm.

The pixel define layer 40 is provided with pixel openings 401 in the active area AA. The display panel further includes light-emitting devices 50, at least part of the light-emitting device 50 being located in the corresponding pixel opening 401. In this embodiment of the present application, the light-emitting device 50 includes a first electrode 510, a light-emitting functional unit 520, and a second electrode 530 that are sequentially stacked in the direction away from the substrate 10. In one embodiment, the first electrode 510 is an anode, and the second electrode 530 is a cathode; or the first electrode 510 is a cathode, and the second electrode 530 is an anode. In this embodiment of the present application, the one or more metal layers of the first blocking portion 210 are located on a side of the first electrode 510 that is close to the substrate 10.

The isolation structure 60 is provided with isolation openings 601 in the active area AA, where an orthographic projection of the isolation opening 601 on the substrate 10 covers an orthographic projection of the corresponding pixel opening 401 on the substrate 10.

The display panel further includes an encapsulation layer 70. In one embodiment, the display panel includes a first encapsulation layer 710. The first encapsulation layer 710 is located on a side of the light-emitting devices 50 that faces away from the substrate 10. The first encapsulation layer 710 includes encapsulation units 711 spaced apart from each other, and the encapsulation units 711 correspond to the light-emitting devices 50. An orthographic projection of the encapsulation unit 711 on the substrate 10 covers at least part of an orthographic projection of the light-emitting device 50 on the substrate 10. The display panel further includes a second encapsulation layer 720 located on a side of the first encapsulation layer 710 that faces away from the substrate 10. The second encapsulation layer 720 extends from the active area AA to the non-active area NA and terminates on a side of the dams 20 that is close to the active area AA. The display panel further includes a third encapsulation layer 730 located on a side of the second encapsulation layer 720 that faces away from the substrate 10. The third encapsulation layer 730 extends from the active area AA to the non-active area NA, and in the non-active area NA, the third encapsulation layer 730 is at least partially in contact with the pixel define layer 40. Materials of the first encapsulation layer 710 and the third encapsulation layer 730 include inorganic materials, and a material of the second encapsulation layer 720 includes an organic material.

In a second aspect, an embodiment of the present application further provides a display panel, which has an active area and a non-active area surrounding the active area. The display panel includes: a substrate; and one or more dams located on a side of the substrate, the dams being located in the non-active area and at least partially surrounding the active area, where the one or more dams include at least one first-type dam, the first-type dam including a second blocking portion, the second blocking portion including a first sub-portion and a second sub-portion that are sequentially stacked in a direction away from the substrate, where an orthographic projection, on the substrate, of an edge of the second sub-portion on a side of the second sub-portion that is away from the active area is within an orthographic projection of the first sub-portion on the substrate.

In one embodiment, the first-type dam further includes a first blocking portion located on a side of the second blocking portion that is close to the substrate, where an orthographic projection of the second blocking portion on the substrate is within an orthographic projection of the first blocking portion on the substrate, and the first blocking portion includes one or more metal layers. In one embodiment, a surface of the second sub-portion on a side of the second sub-portion that is away from the active area is flush with a surface of the first sub-portion on a side of the first sub-portion that is away from the active area; and an orthographic projection, on the substrate, of an edge of the second sub-portion on a side of the second sub-portion that is close to the active area is on a side of an orthographic projection of a surface of the first sub-portion facing the second sub-portion on the substrate that is close to the active area. In one embodiment, the display panel further includes an isolation structure located in the active area and located on a side of the substrate, the second blocking portion being provided in the same layer as the isolation structure. In one embodiment, the isolation structure includes a first portion and a second portion that are sequentially stacked in the direction away from the substrate, the first sub-portion being in the same layer as the first portion, and the second sub-portion being in the same layer as the second portion. In one embodiment, a material of the first sub-portion includes aluminum, and a material of the second sub-portion includes titanium. In one embodiment, the second blocking portion further includes a third sub-portion located on a side of the first sub-portion that is close to the substrate, and the isolation structure further includes a third portion located on a side of the first portion that is close to the substrate, the first sub-portion being in the same layer as the first portion. In one embodiment, a material of the third sub-portion includes molybdenum.

In one embodiment, the one or more dams further include at least one second-type dam, the second-type dam including a third blocking portion, the third blocking portion including at least one insulating layer. In one embodiment, the third blocking portion includes a second insulating layer and a first insulating layer that are sequentially stacked in a direction away from the substrate. In one embodiment, at least one second-type dam includes a second blocking portion located on a side of the third blocking portion that faces away from the substrate, where an orthographic projection of the second blocking portion on the substrate is within an orthographic projection of the third blocking portion on the substrate.

In a third aspect, an embodiment of the present application further provides a display panel, which has an active area and a non-active area surrounding the active area. The display panel includes: a substrate; and one or more dams located on a side of the substrate, the dams being located in the non-active area and at least partially surrounding the active area, where the one or more dams include second-type dams, the second-type dam including a third blocking portion and a second blocking portion that are sequentially stacked in a direction away from the substrate, where an orthographic projection of the second blocking portion on the substrate is within an orthographic projection of the third blocking portion on the substrate, and the third blocking portion includes at least one insulating layer.

In one embodiment, the third blocking portion includes a second insulating layer and a first insulating layer that are sequentially stacked in a direction away from the substrate. In one embodiment, the second blocking portion includes a first sub-portion and a second sub-portion that are sequentially stacked in a direction away from the substrate, where an orthographic projection, on the substrate, of an edge of the second sub-portion on a side of the second sub-portion that is away from the active area is within an orthographic projection of the first sub-portion on the substrate. In one embodiment, a surface of the second sub-portion on a side of the second sub-portion that is away from the active area is flush with a surface of the first sub-portion on a side of the first sub-portion that is away from the active area. In one embodiment, an orthographic projection, on the substrate, of an edge of the second sub-portion on a side of the second sub-portion that is close to the active area is on a side of an orthographic projection of a surface of the first sub-portion facing the second sub-portion on the substrate that is close to the active area. In one embodiment, the display panel further includes an isolation structure located in the active area and located on a side of the substrate, the isolation structure including a first portion and a second portion that are sequentially stacked in the direction away from the substrate, the first sub-portion being in the same layer as the first portion, and the second sub-portion being in the same layer as the second portion. In one embodiment, a material of the first sub-portion includes aluminum, and a material of the second sub-portion includes titanium. In one embodiment, the second blocking portion further includes a third sub-portion located on a side of the first sub-portion that is close to the substrate, and the isolation structure further includes a third portion located on a side of the first portion that is close to the substrate, the first sub-portion being in the same layer as the first portion. In one embodiment, a material of the third sub-portion includes molybdenum.

In one embodiment, the one or more dams further include at least one first-type dam, the first-type dam including a first blocking portion, the first blocking portion including one or more metal layers. In one embodiment, the first-type dam further includes a second blocking portion located on a side of the first blocking portion that faces away from the substrate, where an orthographic projection of the second blocking portion on the substrate is within an orthographic projection of the first blocking portion on the substrate.

In a fourth aspect, an embodiment of the present application further provides a preparation method for a display panel. The method is used for preparing the display panel described above. The display panel includes an active area and a non-active area surrounding the active area. The preparation method includes: preparing one or more dams on a side of a substrate. The dams are located in the non-active area and at least partially surround the active area, where the one or more dams include at least one first-type dam, the first-type dam including a first blocking portion, the first blocking portion including one or more metal layers.

FIG. 11 is a schematic flowchart of a preparation method for a display panel according to an embodiment of the present application. As shown in FIG. 11, the method includes the following steps.

Step S110: Prepare one or more dams on a side of a substrate.

In this embodiment of the present application, the dams are located in the non-active area and at least partially surround the active area, where the one or more dams include first-type dams, the first-type dam including a first blocking portion, the first blocking portion including one or more metal layers.

In this embodiment of the present application, in the case that the dam is the first-type dam, the preparation method includes: preparing a second insulating material layer on a side of the substrate, and patterning the second insulating material layer to obtain a second planarization layer and a second insulating layer; preparing a first metal material layer on a side of the second insulating layer that faces away from the substrate, and patterning the first metal material layer to obtain a third metal layer and a first metal layer; and preparing a first insulating material layer on a side of the first metal layer that faces away from the substrate, and patterning the first insulating material layer to obtain a first planarization layer and a first insulating layer, where the second insulating layer, the first metal layer, and the first insulating layer constitute the first blocking portion.

In one embodiment, before the preparing a second insulating material layer on a side of the substrate, the method further includes preparing a second metal material layer on a side of the substrate, and patterning the second metal material layer to obtain a fourth metal layer and a second metal layer, where the second metal layer, the second insulating layer, the first metal layer, and the first insulating layer constitute the first blocking portion, resulting in the display panel as shown in FIG. 3.

In one embodiment, before the preparing one or more dams on a side of a substrate, the method further includes: preparing a gate drive circuit on a side of the substrate, where the gate drive circuit is located in the non-active area, and an orthographic projection of the gate drive circuit on the substrate is on a side of an orthographic projection of the dams on the substrate that is close to the active area. In one embodiment, the patterning the first metal material layer includes: patterning the first metal material layer, and the first metal layer covers the gate drive circuit; and/or the patterning the second metal material layer includes: patterning the second metal material layer, and the second metal layer covers the gate drive circuit, resulting in the display panel as shown in FIG. 4. In one embodiment, after the preparing a gate drive circuit on a side of the substrate, the method further includes: preparing a third insulating layer on a side of the gate drive circuit that faces away from the substrate. That is, the third insulating layer is provided between the gate drive circuit and the second metal layer to avoid an electrical connection between the two.

In one embodiment, in the case that the dam is the second-type dam, the method further includes: preparing a second insulating material layer on a side of the substrate, and patterning the second insulating material layer to obtain a second planarization layer and a second insulating layer; preparing a first insulating material layer on a side of the second insulating layer that faces away from the substrate, and patterning the first insulating material layer to obtain a first planarization layer and a first insulating layer, where the first insulating layer and the second insulating layer constitute the third blocking portion, as shown in FIGS. 8 to 10. It should be noted that in the case that both the first-type dam and the second-type dam exist, the method includes: sequentially preparing the second metal layer, the second insulating layer, the first metal layer, and the first insulating layer on a side of the substrate. The second metal layer and the first metal layer that correspond to the second-type dam are etched away in respective steps of the preparation process.

In one embodiment, after the preparation of the first planarization layer and the first insulating layer, the method further includes: sequentially preparing a first conductive material layer and a second conductive material layer on a side of the first insulating layer that faces away from the substrate; performing a first patterning process on the first conductive material layer and the second conductive material layer to obtain an intermediate structure, the intermediate structure including a first intermediate sub-structure located in the active area and a second intermediate sub-structure located in the non-active area; coating a photoresist on at least part of a surface of the second intermediate sub-structure that faces away from the substrate; and performing a second patterning process on the first intermediate sub-structure and/or the second intermediate sub-structure, and removing the photoresist to obtain an isolation structure located in the active area and a second blocking portion located in the non-active area, the second blocking portion being located on a side of the first blocking portion and/or the third blocking portion that faces away from the substrate, as shown in FIGS. 5 to 7, FIG. 9, and FIG. 10. In one embodiment, the first patterning process includes dry etching, and the second patterning process includes wet etching.

In one embodiment, the performing a first patterning process on the first conductive material layer and the second conductive material layer to obtain an intermediate structure includes: coating a photoresist on a portion of the second conductive material layer that faces away from the substrate, and performing exposure and development to obtain a patterned photoresist; and performing the first patterning process on portions of the first conductive material layer and the second conductive material layer that are not coated with the photoresist, to obtain the intermediate structure.

In one embodiment, before the sequentially preparing a first conductive material layer and a second conductive material layer on a side of the first insulating layer that faces away from the substrate, the method further includes: preparing a third conductive material layer on a side of the first insulating layer that faces away from the substrate; and after the sequentially preparing a first conductive material layer and a second conductive material layer on a side of the first insulating layer that faces away from the substrate, the method further includes: performing a first patterning process on the first conductive material layer, the second conductive material layer, and the third conductive material layer to obtain an intermediate structure.

In one embodiment, after the preparation of the first planarization layer and the first insulating layer, the method further includes: preparing a pixel define layer on a side of the first insulating layer that faces away from the substrate, where the pixel define layer extends from the active area to the non-active area, the pixel define layer is in contact with the first blocking portion and/or the third blocking portion, and the pixel define layer is provided with pixel openings in the active area.

In one embodiment, before the preparing a pixel define layer on a side of the first insulating layer that faces away from the substrate, the method further includes: preparing first electrodes on the side of the first insulating layer that faces away from the substrate, where the first electrode is partially exposed out of the pixel opening; and after the preparing a pixel define layer on a side of the first insulating layer that faces away from the substrate, the method further includes: sequentially preparing light-emitting functional units and second electrodes on a side of the pixel define layer that faces away from the substrate, where the first electrode, the light-emitting functional unit, and the second electrode constitute a light-emitting device, the light-emitting device being at least partially located within the pixel opening.

In one embodiment, after the preparation of the second electrodes, the method further includes: preparing a first encapsulation layer on a side of the second electrodes that faces away from the substrate, the first encapsulation layer including encapsulation units which are spaced apart from each other and correspond to the light-emitting devices, where an orthographic projection of the encapsulation unit on the substrate covers at least part of an orthographic projection of the corresponding light-emitting device on the substrate.

In one embodiment, after the preparing a first encapsulation layer on a side of the second electrodes that faces away from the substrate, the method further includes: sequentially preparing a second encapsulation layer and a third encapsulation layer on a side of the first encapsulation layer that faces away from the substrate, the second encapsulation layer extending from the active area to the non-active area and terminating on a side of the dams that is close to the active area, where the third encapsulation layer extends from the active area to the non-active area, and in the non-active area, the third encapsulation layer is at least partially in contact with the pixel define layer.

In one embodiment, after the preparation of the third encapsulation layer, the method further includes: preparing a touch trace layer on a side of the third encapsulation layer that faces away from the substrate.

In a fifth aspect, an embodiment of the present application provides a display apparatus. The display apparatus includes the display panel in the above embodiments.

FIG. 12 is a schematic structural diagram of a display apparatus according to an embodiment of the present application. As shown in FIG. 12, the display apparatus 1200 is a product having an image display function. For example, the display apparatus 1200 may be used to display static images, such as pictures or photos. The display apparatus 1200 may also be used to display dynamic images, such as videos.

The display apparatus 1200 may be a laptop computer, a mobile phone, a handheld or portable computer, a camera, a video camera, an in-vehicle infotainment display, a calculator, a smart watch, a GPS navigator, an electronic photograph, an electronic billboard or signboard, a projector, or the like.

The display apparatus 1200 includes a display panel according to any one of the above embodiments. The display panel may be an organic light-emitting diode display panel or a quantum dot electroluminescent display panel.

In addition, the display apparatus 1200 may also have functions of photographing, video recording, fingerprint recognition, face recognition, etc. Accordingly, the display apparatus 1200 further includes at least one functional module for implementing the above functions, such as an under-display camera, or an under-display fingerprint recognition sensor.

The basic principle of the present application is described above with respect to particular embodiments, but it should be noted that the benefits, advantages, effects, and the like mentioned in the present application are merely exemplary rather than limiting, and may not be considered as required for each embodiment of the present application. In addition, the specific details disclosed above are only for the purpose of illustration and ease of understanding instead of limitations, and the above details do not limit the present application as implemented by necessarily employing the above specific details.

The block diagrams of components, apparatuses, devices, and systems involved in the present application are merely illustrative examples and are not intended to require or imply that they must be connected, arranged, or configured in the manner shown in the block diagrams. The components, apparatuses, devices, and systems may be connected, arranged, or configured in any manner. The words such as “including”, “comprising”, and “having” are open words, meaning “including but not limited to”, and can be used interchangeably therewith. The words “or” and “and” used herein refer to the words “and/or” and can be used interchangeably therewith, unless the context clearly indicates otherwise. The word “such as” used herein refers to the phrase “such as but not limited to”, and can be used interchangeably therewith.

It should also be noted that in the apparatus, device, and method of the present application, each component or each step can be decomposed and/or recombined. These decompositions and/or recombinations should be regarded as equivalent solutions of the present application.

Various modifications to these aspects will be readily apparent in the art, and the general principles defined herein may be applied to other aspects without departing from the scope of the present application. Therefore, the present application is not intended to be limited to the aspects shown herein, but to be in the broadest scope consistent with the principles and novel features disclosed herein.

The above description has been given for purposes of illustration and description. Moreover, this description is not intended to limit the embodiments of the present application to the form disclosed herein.

1. A display panel, which has an active area and a non-active area surrounding the active area, the display panel comprising:
a substrate;
an isolation structure located on a side of the substrate, the isolation structure being provided with a plurality of isolation openings in the active area;
a plurality of light-emitting devices, at least part of each of the light-emitting devices being located in the corresponding isolation opening, and the light-emitting device comprising a first electrode, a light-emitting functional unit, and a second electrode that are stacked in a direction away from the substrate; and
at least one dam located on a side of the substrate, at least one dam being located in the non-active area and at least partially surrounding the active area,
wherein the at least one dam comprises at least one first-type dam, the at least one first-type dam comprising a first blocking portion, the first blocking portion comprising at least one metal layer located on a side of the first electrode that is close to the substrate.

2. The display panel according to claim 1, wherein the first blocking portion further comprises a first insulating layer, and the at least one metal layer is located on a side of the first insulating layer that is close to the substrate.

3. The display panel according to claim 2, wherein the first blocking portion further comprises a second insulating layer located on a side of the first insulating layer that is close to the substrate, and the at least one metal layer comprises a first metal layer located between the first insulating layer and the second insulating layer.

4. The display panel according to claim 3, wherein the at least one metal layer further comprises a second metal layer located on a side of the second insulating layer that is close to the substrate.

5. The display panel according to claim 4, wherein an orthographic projection of the first insulating layer on the substrate covers an orthographic projection of the first metal layer on the substrate, and an orthographic projection of the second insulating layer on the substrate covers an orthographic projection of the second metal layer on the substrate.

6. The display panel according to claim 1, wherein the display panel further comprises a gate drive circuit located in the non-active area, wherein an orthographic projection of the gate drive circuit on the substrate is on a side of an orthographic projection of the at least one dam on the substrate that is close to the active area; at least one metal layer extends, in a direction of the active area, to a side of the gate drive circuit that faces away from the substrate; and the display panel further comprises a third insulating layer located between the gate drive circuit and the at least one metal layer.

7. The display panel according to claim 6, wherein an orthographic projection of the at least one metal layer on the substrate covers the orthographic projection of the gate drive circuit on the substrate;
the at least one metal layer is configured to be connected to a constant potential; and
the display panel further comprises a touch trace layer located on a side of the at least one metal layer that faces away from the substrate, wherein an orthographic projection of the touch trace layer on the substrate at least partially overlaps the orthographic projection of the gate drive circuit on the substrate.

8. The display panel according to claim 1, wherein at least one first-type dam further comprises a second blocking portion located on a side of the first blocking portion that faces away from the substrate;
an orthographic projection of the second blocking portion on the substrate is within an orthographic projection of the first blocking portion on the substrate;
the second blocking portion comprises a first sub-portion and a second sub-portion that are sequentially stacked in a direction away from the substrate, wherein an orthographic projection, on the substrate, of an edge of the second sub-portion on a side of the second sub-portion that is away from the active area is within an orthographic projection of the first sub-portion on the substrate; or the second blocking portion comprises a first sub-portion and a second sub-portion that are sequentially stacked in a direction away from the substrate, wherein a surface of the second sub-portion on a side of the second sub-portion that is away from the active area is flush with a surface of the first sub-portion on a side of the first sub-portion that is away from the active area; and an orthographic projection, on the substrate, of an edge of the second sub-portion on a side of the second sub-portion that is close to the active area is on a side of an orthographic projection of a surface of the first sub-portion facing the second sub-portion on the substrate that is close to the active area.

9. The display panel according to claim 8, wherein the isolation structure comprises a first portion and a second portion that are sequentially stacked in the direction away from the substrate, the first sub-portion being in the same layer as the first portion, and the second sub-portion being in the same layer as the second portion.

10. The display panel according to claim 9, wherein the second blocking portion further comprises a third sub-portion located on a side of the first sub-portion that is close to the substrate, and the isolation structure further comprises a third portion located on a side of the first portion that is close to the substrate, the first sub-portion being in the same layer as the first portion.

11. The display panel according to claim 1, wherein the at least one dam comprises a first dam and a second dam surrounding the first dam, wherein the first dam is the first-type dam, the second dam is the first-type dam, and the first dam comprises a second blocking portion located on a side of the first blocking portion that faces away from the substrate, or the first dam and the second dam each comprise a second blocking portion located on a side of the first blocking portion that faces away from the substrate.

12. The display panel according to claim 1, wherein the at least one dam comprises at least one second-type dam, the at least one second-type dam comprising a third blocking portion;
the at least one dam comprises a third dam and a fourth dam surrounding the third dam, wherein the third dam is the first-type dam and the fourth dam is the second-type dam, or the fourth dam is the first-type dam and the third dam is the second-type dam; and
the third blocking portion comprises a second insulating layer and a first insulating layer that are sequentially stacked in a direction away from the substrate.

13. The display panel according to claim 1, further comprising a pixel define layer partially located in the non-active area, wherein in the non-active area, an orthographic projection of the pixel define layer on the substrate covers an orthographic projection of the at least one dam on the substrate;
a material of the pixel define layer comprises an inorganic material; and
the pixel define layer is in contact with the first blocking portion.

14. The display panel according to claim 13, wherein the at least one first-type dam further comprises a second blocking portion, wherein an orthographic projection of the second blocking portion on the substrate is within an orthographic projection of the first blocking portion on the substrate, and the second blocking portion is located on a side of the pixel define layer that faces away from the substrate.

15. The display panel according to claim 13, wherein the pixel define layer is provided with a plurality of pixel openings in the active area, wherein an orthographic projection of the isolation opening on the substrate covers an orthographic projection of the corresponding pixel opening on the substrate;
the display panel further comprises a first encapsulation layer located on a side of the light-emitting devices that faces away from the substrate, the first encapsulation layer comprising a plurality of encapsulation units which are spaced apart from each other and correspond to the light-emitting devices, wherein an orthographic projection of the encapsulation unit on the substrate covers at least part of an orthographic projection of the corresponding light-emitting device on the substrate; and
the display panel further comprises a second encapsulation layer located on a side of the first encapsulation layer that is away from the substrate, the second encapsulation layer extending from the active area to the non-active area and terminating on a side of the at least one dam that is close to the active area.

16. A display panel, which has an active area and a non-active area surrounding the active area, the display panel comprising:
a substrate; and
at least one dam located on a side of the substrate, the at least one dam being located in the non-active area and at least partially surrounding the active area,
wherein the at least one dam comprises at least one first-type dam, the at least one first-type dam comprising a second blocking portion, the second blocking portion comprising a first sub-portion and a second sub-portion that are sequentially stacked in a direction away from the substrate, wherein an orthographic projection, on the substrate, of an edge of the second sub-portion on a side of the second sub-portion that is away from the active area is within an orthographic projection of the first sub-portion on the substrate.

17. The display panel according to claim 16, wherein the at least one first-type dam further comprises a first blocking portion located on a side of the second blocking portion that is close to the substrate, the first blocking portion comprising at least one metal layer.

18. A display panel, which has an active area and a non-active area surrounding the active area, the display panel comprising:
a substrate; and
at least one dam located on a side of the substrate, the at least one dam being located in the non-active area and at least partially surrounding the active area,
wherein the at least one dam comprises at least one second-type dam, the at least one second-type dam comprising a third blocking portion and a second blocking portion that are sequentially stacked in a direction away from the substrate, wherein an orthographic projection of the second blocking portion on the substrate is within an orthographic projection of the third blocking portion on the substrate, and the third blocking portion comprises at least one insulating layer.

19. The display panel according to claim 18, wherein the third blocking portion comprises a second insulating layer and a first insulating layer that are sequentially stacked in a direction away from the substrate; and
the second blocking portion comprises a first sub-portion and a second sub-portion that are sequentially stacked in the direction away from the substrate, wherein an orthographic projection, on the substrate, of an edge of the second sub-portion on a side of the second sub-portion that is away from the active area is within an orthographic projection of the first sub-portion on the substrate.

20. The display panel according to claim 18, wherein the at least one dam further comprises at least one first-type dam, the at least one first-type dam comprising a first blocking portion, the first blocking portion comprising at least one metal layer; and
the at least one first-type dam further comprises a second blocking portion located on a side of the first blocking portion that faces away from the substrate, wherein an orthographic projection of the second blocking portion on the substrate is within an orthographic projection of the first blocking portion on the substrate.
